(19) United States
(12) Patent Application Publication
(10) Pub. No.: US 2010/0231280 A1
(43) Pub. Date: Sep. 16, 2010

(54) DELAY CELL THAT INVERSELY RESPONDS TO TEMPERATURE

(76) Inventor: Hyun-Bae Lee, Hwaseong-si (KR)

Correspondence Address: F. CHAU & ASSOCIATES, LLC, 130 WOODBURY ROAD, WOODBURY, NY, 11797, US

(21) Appl. No.: 12/708,999

(22) Filed: Feb. 19, 2010

(30) Foreign Application Priority Data
Mar. 11, 2009 (KR) 10-2009-0020859

(51) Int. Cl. H03H 11/26

(52) U.S. Cl. 327/262

(57) ABSTRACT

A delay cell structure that inversely responds to temperature is provided. A first current mirror includes first and second transistors having sources commonly connected to a power supply terminal. A second current mirror includes third and fourth transistors having drains connected to the channels of the first and second transistors and sources commonly connected to a ground terminal. A resistor is connected between the drains of the first and second transistors. An inverter is provided between the drains of the second and fourth transistors so as to face the resistor and outputting a delay signal that is later than input signal by a delay time proportional to the threshold voltages of the first and third transistors which vary as a function of temperature.

### CROSS-REFERENCE TO RELATED APPLICATION

This patent application claims priority to and the benefit of Korean Patent Application 10-2009-0020589, filed on Mar. 11, 2009, in the Korean Intellectual Property Office, the entire content of which is incorporated by reference herein.

### BACKGROUND

1. Technical Field

The present disclosure relates to delay cells, and, more particularly, to delay cell circuits responsive to temperature.

2. Discussion of the Related Art

In general, electronic circuits respond more rapidly at a low temperature than at a high temperature due to, for example, phonon vibration or atomic vibration. Therefore, it is possible to forcibly reduce the temperature of a high-speed and high-performance system using a cooler.

However, threshold voltages related to the turn-on operation of transistors are high at a low temperature due to an increase in the band gap of a material. Therefore, in some cases, a small-signal analog circuit that operates around the threshold voltage of the transistor responds more slowly at a low temperature than at a high temperature. When the circuit that operates more slowly at a low temperature than at a high temperature is used, other circuits need to be operated more slowly at a low temperature. A representative example of such other circuit is a delay cell. However, the conventional delay cell is typically an inverter type that responds more rapidly at a low temperature than at a high temperature. Therefore, a delay cell is needed that operates rapidly at high temperature and slowly at low temperature.

### SUMMARY

According to an exemplary embodiment a delay cell is provided that responds inversely to temperature such that it operates more slowly at a low temperature than at a high temperature.

According to an exemplary embodiment, a delay cell structure that inversely responds to temperature includes a first current mirror including a first transistor and a second transistor, the first transistor and the second transistor each having a source connected to a common power supply terminal. A second current mirror includes a third transistor and a fourth transistor, the third transistor and the fourth transistor each having a source connected to a common ground terminal. A resistance is connected between drains of the first transistor and the third transistor. An inverter, connected between drains of the second transistor and the fourth transistor, outputs a delay signal that is proportional to threshold voltages of the first transistor and the third transistor that vary as a function of temperature.

The first current mirror and the second current mirror are single-ended amplifiers.

Each of the first transistor and the third transistor of the single-ended amplifiers may have a diode connection structure.

The first transistor and the second transistor may be PMOS transistors.

The third transistor and the fourth transistor may be NMOS transistors.

The source and the gate of the first transistor may be connected to each other, and the drain and the gate of the third transistor may be connected to each other.

The delay cell structure may further include a first dummy resistor provided between the power supply terminal and the first transistor, and a second dummy resistor provided between the third transistor and the ground terminal. The resistance may be a short circuit between the drain of the first transistor and the drain of the second transistor.

According to an exemplary embodiment, a delay cell structure that inversely responds to temperature is provided. A first bias controller includes a first-conduction-type first MOS transistor having a drain connected to a power supply terminal and a gate connected to a signal input terminal and a second-conduction-type first MOS transistor having a gate connected to a source of the first-conduction-type first MOS transistor and a source connected to the power supply terminal. A second bias controller includes a second-conduction-type second MOS transistor having a gate connected to the signal input terminal and a drain connected to a ground terminal and a first-conduction-type second MOS transistor having a gate connected to a source of the second-conduction-type second MOS transistor and a source connected to the ground terminal. A resistance is connected between the source of the first-conduction-type first MOS transistor and the source of the second-conduction-type second MOS transistor. An inverter is connected between the drain of the second-conduction-type first MOS transistor and the drain of the first-conduction-type second MOS transistor, faces the resistance and outputs a delay signal that is later than an input signal by a delay time proportional to threshold voltages of the first-conduction-type first MOS transistor and the second-conduction-type second MOS transistor that vary as a function of temperature.

The inverter may include a second-conduction-type third MOS transistor having a source connected to the drain of the second-conduction-type first MOS transistor and a gate connected to the signal input terminal, and a first-conduction-type third MOS transistor having a drain connected to the drain of the second-conduction-type third MOS transistor, a gate connected to the signal input terminal, and a source connected to the drain of the first-conduction-type second MOS transistor.

The delay cell structure may further include a first dummy resistor connected between the power supply terminal and the first-conduction-type first MOS transistor, and a second dummy resistor connected between the ground terminal and the second-conduction-type second MOS transistor. The resistance may be a short circuit between the source of the first-conduction-type first MOS transistor and the source of the second-conduction-type second MOS transistor.

According to an exemplary embodiment a delay cell includes an inverter having an input terminal and an output terminal, and a first current mirror and a second current mirror, each current mirror disposed between a common power supply terminal and a common ground terminal and having current mirror transistors that operate more slowly at a first temperature than they operate at a second temperature higher than the first temperature, the first current mirror and the second current mirror configured to provide a power supply delay to the inverter.

The delay cell may further include a resistance disposed in parallel with the inverter and coupled between the first current mirror and the second current mirror.

Each current mirror transistor may operate in a dip saturation region.

When temperature decreases, threshold voltages of the current mirror transistors may increase and when temperature increases, threshold voltages of the current mirror transistors may decrease.

A predetermined delay time between a signal input to the inverter and a signal output from the inverter may be determined by a resistance value of the resistance.

The resistance value of the resistance may vary less with temperature than a threshold voltage of the current mirror transistors varies with temperature.

The delay cell may further include a first resistance between the first current mirror and the power supply terminal, and a second resistance coupled between the second current mirror and the ground terminal.

The first resistance and the second resistance may have substantially the same resistance value.

### BRIEF DESCRIPTION OF THE DRAWINGS

Exemplary embodiments of the invention concept will be described below with reference to the attached drawings in which:

FIG. 1 is a diagram schematically illustrating a conventional temperature responsive delay cell;

FIG. 2 is a graph illustrating the correlation between a voltage applied between the gate and the source of a MOS transistor and a current flowing through a channel;

FIGS. 3A and 3B are circuit diagrams illustrating delay cells that inversely respond to temperature according to an exemplary embodiment of the inventive concept;

FIG. 4 is a diagram illustrating a delay signal output from the delay cells of FIGS. 3A and 3B;

FIGS. 5A and 5B are circuit diagrams illustrating delay cells that inversely respond to temperature according to an exemplary embodiment of the inventive concept; and

FIG. 6 is a diagram illustrating a delay signal output from the delay cells of FIGS. 5A and 5B.

### DETAILED DESCRIPTION

Specific structural and functional details disclosed herein are merely representative for purposes of describing exemplary embodiments. Exemplary embodiments may, however, may be embodied in many alternate forms and should not be construed as limited to only the embodiments set forth herein. Like numbers refer to like elements throughout the description of the figures.

It will be understood that, although the terms first, second and third may be used herein to describe various elements, these elements should not be limited by these terms. These terms are only used to distinguish one element from another. For example, a first element could be termed a second element, and, similarly, a second element could be termed a first element, without departing from the scope of exemplary embodiments. As used herein, the term “and/or” includes any and all combinations of one or more of the associated listed items.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between”, “adjacent” versus “directly adjacent”, etc.).

Hereinafter, delay cells that inversely respond to temperature according to exemplary embodiments of the inventive concept will be described in detail with reference to the accompanying drawings.

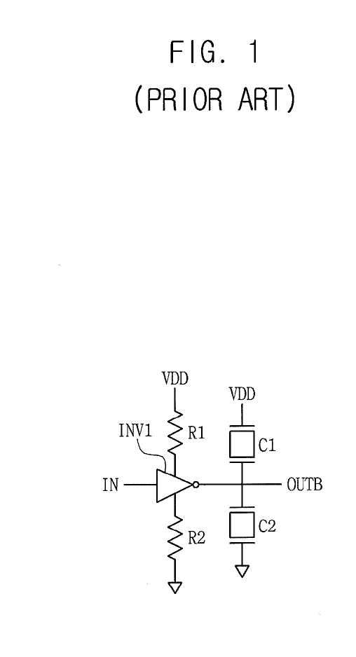

For ease of understanding of the functions and operations of the following exemplary embodiments of the inventive concept, the circuit diagram of FIG. 1 that illustrates an inverter-type temperature responsive delay cell will be first described.

FIG. 1 is a diagram schematically illustrating a conventional temperature responsive delay cell.

As shown in FIG. 1, the conventional temperature responsive delay cell includes an inverter INV1 connected in series with one or more resistors R1, R2 between a power supply terminal VDD and a ground terminal and one or more capacitors C1, C2 formed at an output terminal of the inverter INV1. The resistances of the resistors R1, R2 and the capacitances of the capacitors C1, C2 may vary as a function of the kind of materials and/or temperature variation. The inverter INV1 may more sensitively respond to the temperature than the resistors R1, R2 and the capacitors C1, C2 and the operational speed thereof may be changed rapidly.

That is, the operational speed of a MOS transistor of the inverter INV1 may be affected by the temperature. For example, the MOS transistor of the inverter INV1 operates in a linear region and is turned on more rapidly at a low temperature than at a high temperature. This may be represented by Expression 1 given below:

$${I}_{D} = k \cdot \frac{{μ}_{0}}{{T}^{1.5}} \cdot [ ( {V}_{GS} - {V}_{TH 0} + α \cdot T ) \cdot {V}_{DS} - \frac{{V}_{DS}^{2}}{2} ] \\ ( where \frac{\partial {I}_{D}}{\partial T} < 0 ) . \qquad [ Expression 1 ]$$

The linear region satisfies V_{DS}≦V_{GS}−V_{TH}, and mainly appears when the inverter INV1 processes digital signals. The circuit operating in the linear region responds more rapidly at a low temperature than at a high temperature.

On the other hand, a circuit operating in a saturation region may respond more rapidly at a high temperature than at a low temperature under dip saturation conditions represented by Expression 2 given below:

$${I}_{D} = \frac{k}{2} \cdot \frac{{μ}_{0}}{{T}^{1.5}} \cdot {( {V}_{GS} - {V}_{TH 0} + α \cdot T )}^{2} \\ ( where \frac{\partial {I}_{D}}{\partial T} > 0 and \frac{aT}{3} > {V}_{GS} - {V}_{TH 0} ) . \qquad [ Expression 2 ]$$

The saturation region satisfies V_{DS}≧V_{GS}−V_{TH}, and mainly appears when an analog signal is used to turn on a transistor.

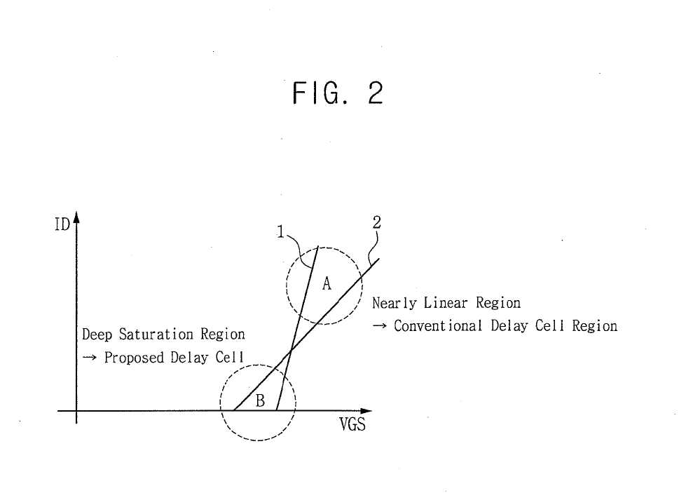

FIG. 2 is a graph illustrating the correlation between a voltage applied between the gate and source of the MOS transistor and the amount of current flowing through a channel. The MOS transistor is turned on more slowly at a high temperature than at a low temperature in a linear region A.

On the other hand, the MOS transistor is turned on more slowly at a low temperature than at a high temperature in a dip saturation region B. In the dip saturation region B, the inclination of a turn-on operation graph 1 of a MOS transistor at a low temperature is large, and the inclination of a turn-on operation graph 2 of a MOS transistor at a high temperature is small. In particular, in the dip saturation region B, as the temperature is reduced, the threshold voltage of the MOS transistor is increased. On the other hand, as the temperature is increased, the threshold voltage of the MOS transistor is reduced. The circuit operating in the dip saturation region B may be effectively used as an analog circuit to control a structure having sensitivity as an important factor.

Therefore, an exemplary embodiment of the inventive concept provides a delay cell that inversely responds to temperature and that has a current mirror or a bias control structure that operates in the dip saturation region B and operates more slowly at a low temperature than at a high temperature.

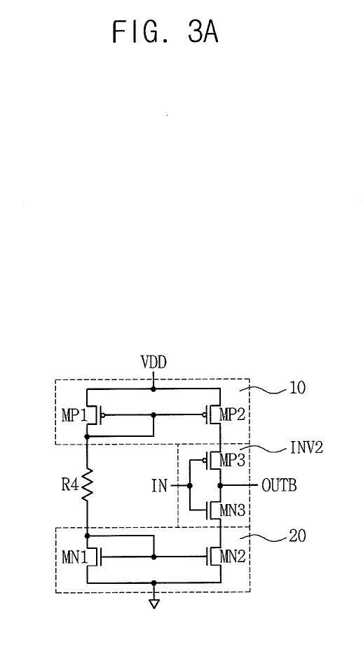

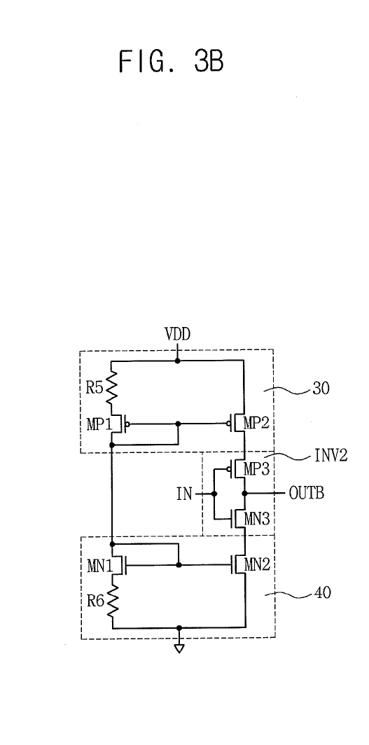

FIGS. 3A and 3B are circuit diagrams illustrating delay cells that inversely respond to temperature according to an exemplary embodiment of the inventive concept.

As shown in FIGS. 3A and 3B, the delay cell that inversely responds to temperature according to the exemplary embodiment of the inventive concept may develop a delay signal that operates more slowly at a low temperature than at a high temperature using a plurality of current mirrors 10, 20 that operate in the dip saturation region between a power supply terminal VDD and a ground terminal.

The delay signal may be output through an inverter INV2 that faces a resistor R4 formed at one side between the current mirrors 10, 20. Therefore, the inverter INV2 may output the delay signal through current mirrors 10, 20 that operate in the dip saturation region. That is, when a signal is input to a signal input terminal IN of the inverter INV2, a power supply delay occurs in the current mirrors 10, 20 that operate more slowly at low temperature than at high temperature in the dip saturation region. The delayed signal is then output to an output terminal OUTB of the inverter INV2.

The current mirrors 10, 20 include first current mirror 10 having first and second PMOS transistors MP1, MP2 whose sources are commonly connected to the power supply terminal VDD and the second current mirror 20 having first and second NMOS transistors MN1, MN2 whose drains connected to the channels of the first PMOS transistor MP1 and the second PMOS transistor MP2 and whose sources are commonly connected to the ground terminal.

Each of the first PMOS transistor MP1 and the first NMOS transistor MN1 may have a diode structure in which the gate and the drain are connected to each other. As described above, the two transistors MP1, MN1 have diode structures that operate in the saturation region, and may control a bias current applied to the inverter INV2 through the second PMOS transistor MP2 and the second NMOS transistor MN2 between the power supply terminal VDD and the ground terminal. Therefore, the first current mirror 10 and the second current mirror 20 may be referred to as single-ended amplifiers capable of obtaining an output voltage through the drain of each of the second PMOS transistor MP2 and the second NMOS transistor MN2.

The resistance of the diode connection structure of each of the first PMOS transistor MP1 and the first NMOS transistor MN1 is very small. Therefore, resistor R4 is formed between the drain of the first PMOS transistor MP1 and the source or the drain of the first NMOS transistor MN1. A predetermined delay time is determined by the resistance value of the resistor R4. The resistor R4 enables the delay cell to be stably operated even when a power level is low. For example, as the resistance value of the resistor is increased, the delay time may be increased.

As shown in FIG. 3A, the resistor R4 and the inverter INV2 are in parallel formed between the current mirrors 10, 20. The resistor R4 may compensate for the low resistance value of each of the first PMOS transistor MP1 and the first NMOS transistor MN1 having a diode structure and prevent the current between the power supply terminal VDD and the ground terminal from flowing without passing through the inverter INV2. The resistance value of the resistor R4 may vary as a function of the kind of materials and the temperature. However, a variation in the resistance value of the resistor R4 may be significantly less than a variation in the threshold voltage of each of the first PMOS transistor MP1 and the first NMOS transistor MN1.

Referring now to FIG. 3B, a first dummy resistor R5 and a second dummy resistor R6 may be provided in the first current mirror 30 and the second current mirror 40, respectively. In this case, the first dummy resistor R5 is formed between the source of the first PMOS transistor MP1 and the power supply terminal VDD, and the second dummy resistor R6 is formed between the source of the first NMOS transistor MN1 and the ground terminal. The first dummy resistor R5 and the second dummy resistor R6 have the same or similar resistance value. If the first dummy resistor R5 and the second dummy resistor R6 have different resistance values, there may be a hysteresis loop in the output of the signal applied through the inverter INV2. The resistor R4 of FIG. 3A between the first PMOS transistor MP1 and the first NMOS transistor MN1 is now in FIG. 3B a short circuit resistance between the first PMOS transistor MP1 and the first NMOS transistor MN1. However, although not shown in the drawings, one or more resistors may be further provided between the drain of the first PMOS transistor MP1 and the drain of the first NMOS transistor MN1.

The inverter INV2 includes a third PMOS transistor MP3 having a source connected to the drain of the second PMOS transistor MP2 and a gate connected to a signal input terminal IN and a third NMOS transistor MN3 having a drain connected to the drain of the third PMOS transistor MP3, a gate connected to the signal input terminal, and a source connected to the drain of the second NMOS transistor MN2. When a signal is input to the signal input terminal IN, the inverter may receive the power supply voltage from the first current mirror 30 and the second current mirror 40 that further delay the power supply voltage at low temperature than at a high temperature and output the delay signal to a signal output terminal OUTB.

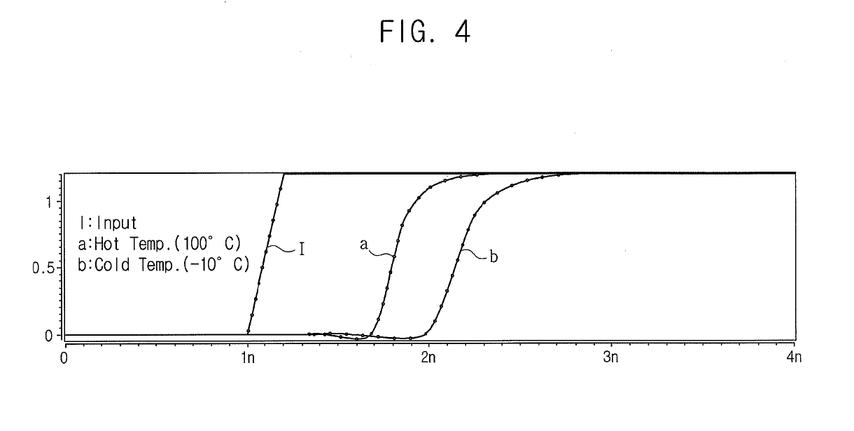

FIG. 4 is a diagram illustrating the delay signal output from the delay cell that inversely responds to temperature according to the exemplary embodiments depicted in FIGS. 3A and 3B. The delay signal at low temperature is later than that at a high temperature. An output signal “a” later than an input signal I by about 0.7 nsec is obtained at a high temperature of about 100° C., and an output signal “b” later than the input signal I by about 1 nsec is obtained at a low temperature of about −10° C. An internal power supply voltage V_{DD} in the range of 1 V to 1.2 V is applied to the power supply terminal VDD. Therefore, a desired operation that inversely responds to the temperature may be performed even when a power level is low. In addition, operations that are affected by temperature may be performed under specific bias conditions. An operation that inversely responds to the temperature input may be performed even at a high input voltage of about 2 V or a low input voltage of about 1 V.

Therefore, the delay cell that inversely responds to temperature according to the exemplary embodiments of the inventive concept of FIGS. 3A and 3B can obtain an output signal that is delayed longer at a low temperature than at a high temperature using a plurality of current mirrors 10, 20 having MOS transistors that operate in the saturation region.

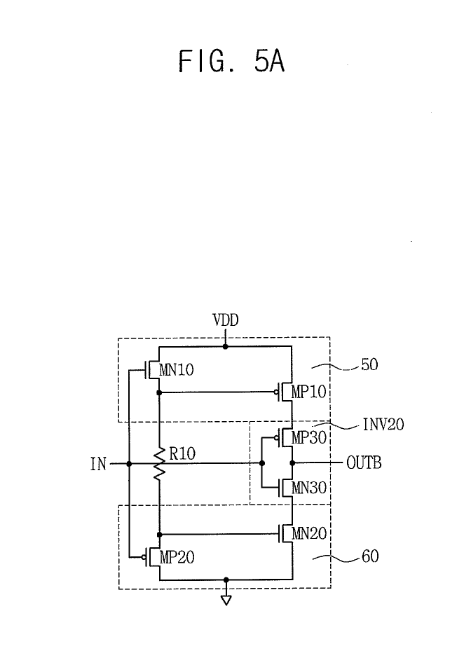

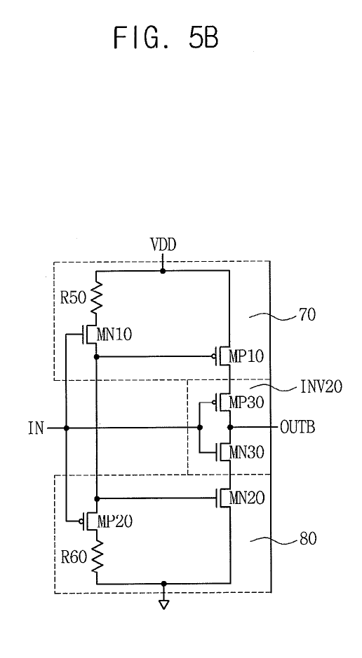

FIGS. 5A and 5B are circuit diagrams illustrating delay cells inversely responding to temperature according to an exemplary embodiment of the inventive concept.

As shown in FIGS. 5A and 5B, the delay cells that inversely respond to temperature according to the exemplary embodiment can obtain an output signal that is delayed longer at a low temperature than at a high temperature using a plurality of bias controllers 50, 60 of FIG. 5A, and bias controllers 70, 80 of FIG. 5B, that respectively operate in the saturation region between the power supply terminal VDD and the ground terminal. In FIG. 5A, a resistor R10 is formed at one side between the plurality of bias controllers 50, 60, and an inverter INV20 is formed at the other side facing the resistor R10. When an input signal is input at terminal IN, the inverter INV20 may receive a power supply voltage having a predetermined time delay through the plurality of bias controllers 50, 60 that operate in the dip saturation region and output a delay signal at terminal OUTB.

The first bias controller 50 includes a first NMOS transistor MN10 having a drain connected to the power supply terminal VDD and a gate connected to the signal input terminal IN and a first PMOS transistor MP10 having a gate connected to the source of the first NMOS transistor MN10 and a source connected to the power supply terminal VDD, and the second bias controller 60 including a second PMOS transistor MP20 having a gate connected to the signal input terminal IN and a drain connected to the ground terminal and a second NMOS transistor MN2 having a gate connected to the source of the second PMOS transistor MP20 and a source connected to the ground terminal.

The first NMOS transistor MN10 and the second PMOS transistor MP20 operate in the saturation region and may control a bias current applied through the first PMOS transistor MP10 and the second NMOS transistor MN2 between the power supply terminal VDD and the ground terminal.

A resistor R10 is formed between the source of the first NMOS transistor MN10 and the source of the second PMOS transistor MP20 such that the bias current flows through the inverter INV20. In this case, the delay time is determined by the resistance value of the resistor R10. The resistor R10 enables the delay cell to be stably operated even through a power level is low.

As shown in FIG. 5A, the resistor R10 and the inverter INV20 are in parallel formed between the plurality of bias controllers 50, 60. As described above, the resistance value of the resistor R10 between the source of the first NMOS transistor MN10 and the source of the second PMOS transistor MP20 may be increased such that the current induced between the power supply terminal VDD and the ground terminal flows through the inverter INV2. The resistance value of the resistor R10 may vary as a function of temperature and the kind of materials. However, a variation in the resistance value of the resistor R10 may be significantly less than a variation in the threshold voltage of each of the first NMOS transistor MN10 and the second PMOS transistor MP20.

Referring to FIG. 5B, a first dummy resistor R50 and a second dummy resistor R60 may be provided in the first bias controller 70 and the second bias controller 80, respectively. In this case, the first dummy resistor R50 is formed between the drain of the first NMOS transistor MN10 and the power supply terminal VDD, and the second dummy resistor R60 is formed between the drain of the second PMOS transistor MP20 and the ground terminal. The first dummy resistor R50 and the second dummy resistor R60 have the same or similar resistance value. If the first dummy resistor R50 and the second dummy resistor R60 have different resistance values, there may be a hysteresis loop in the output of the signal applied through the inverter INV20, which results in a reduction in the reliability of signal processing. The resistor R10 of FIG. 5A between the first NMOS transistor MN10 and the second PMOS transistor MP20 is now in FIG. 5B a short circuit resistance between the first NMOS transistor MN10 and the second PMOS transistor MP20. However, although not shown in the drawings, one or more resistors may be further provided between the source of the first NMOS transistor MN10 and the source of the second PMOS transistor MP20.

The inverter INV20 includes a third PMOS transistor MP30 having a source connected to the drain of the first PMOS transistor MP10 and a gate connected to the signal input terminal and a third NMOS transistor MN30 having a drain connected to the drain of the third PMOS transistor MP30, a gate connected to the signal input terminal IN, and a source connected to the drain of the second NMOS transistor MN20. When a signal is input to the signal input terminal IN, the inverter INV20 may receive the power supply voltage from the first bias controller 70 and the second bias controller 80 that further delay the power supply voltage at a low temperature than at a high temperature and output the delay signal to the signal output terminal OUTB.

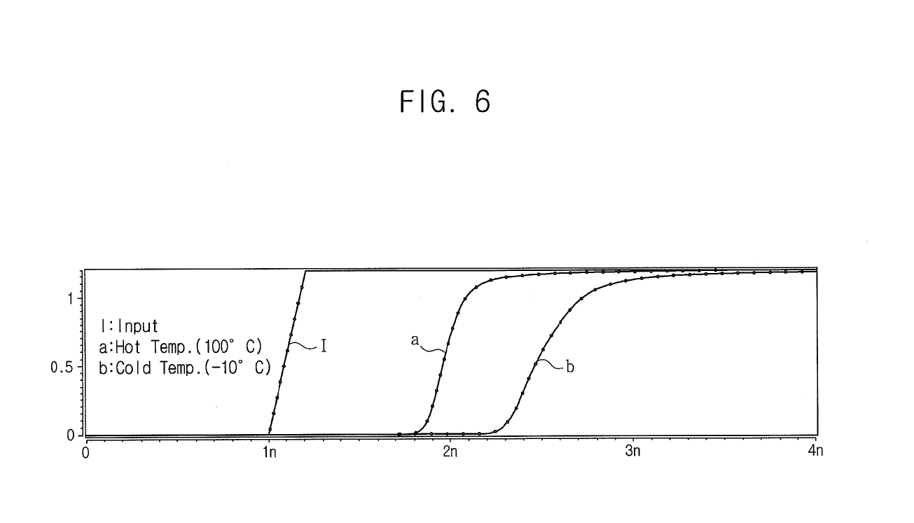

FIG. 6 is a diagram illustrating the delay signal output from the delay cells that inversely respond to temperature according to the exemplary embodiments depicted in FIGS. 5A and 5B. The delay signal at a low temperature is later than that at a high temperature. An output signal “a” later than an input signal I by about 0.8 nsec is obtained at a high temperature of about 100° C., and an output signal “b” later than the input signal I by about 1.3 nsec is obtained at a low temperature of about −10° C. A desired operation that inversely responds to the temperature may be performed even when a low voltage of about 1.2 V is supplied to the power supply terminal VDD. In addition, operations that are insensitive and sensitive to the temperature may be performed under specific bias conditions. An operation that inversely responds to the temperature may be performed even at a high input voltage of about 2 V or a low input voltage of about 1 V.

Therefore, the delay cells that inversely respond to temperature according to the exemplary embodiments of FIGS. 5A and 5B can obtain an output signal that is later at a low temperature than at a high temperature using a bias controllers 50, 60, 70, 80 including the first NMOS transistor MN10 and the second PMOS transistor MP20 that operate in the saturation region.

While the exemplary embodiments of the inventive concept have been shown and described with reference to the drawings, it will be understood by one of ordinary skill in the art that various changes in form and details may be made therein without departing from the spirit and scope of the exemplary embodiments as defined by the following claims.

What is claimed is:

1. A delay cell structure that inversely responds to temperature, comprising:
a first current mirror including a first transistor and a second transistor, the first transistor and the second transistor each having a source connected to a common power supply terminal;
a second current mirror including a third transistor and a fourth transistor, the third transistor and the fourth transistor each having a source connected to a common ground terminal;
a resistance connected between drains of the first transistor and the third transistor; and
an inverter, connected between drains of the second transistor and the fourth transistor, that outputs a delay signal that is proportional to threshold voltages of the first transistor and the third transistor that vary as a function of temperature.

2. The delay cell structure of claim 1, wherein the first current mirror and the second current mirror are single-ended amplifiers.

3. The delay cell structure of claim 2, wherein each of the first transistor and the third transistor of the single-ended amplifiers has a diode connection structure.

4. The delay cell structure of claim 3, wherein the first transistor and the second transistor are PMOS transistors.

5. The delay cell structure of claim 3, wherein the third transistor and the fourth transistor are NMOS transistors.

6. The delay cell structure of claim 4 or 5, wherein the source and the gate of the first transistor are connected to each other, and the drain and the gate of the third transistor are connected to each other.

7. The delay cell structure of claim 1, further comprising:
a first dummy resistor provided between the power supply terminal and the first transistor; and
a second dummy resistor provided between the third transistor and the ground terminal,
wherein the resistance is a short circuit between the drain of the first transistor and the drain of the second transistor.

8. A delay cell structure that inversely responds to temperature, comprising:
a first bias controller including a first-conduction-type first MOS transistor having a drain connected to a power supply terminal and a gate connected to a signal input terminal and a second-conduction-type first MOS transistor having a gate connected to a source of the first-conduction-type first MOS transistor and a source connected to the power supply terminal;
a second bias controller including a second-conduction-type second MOS transistor having a gate connected to the signal input terminal and a drain connected to a ground terminal and a first-conduction-type second MOS transistor having a gate connected to a source of the second-conduction-type second MOS transistor and a source connected to the ground terminal;
a resistance connected between the source of the first-conduction-type first MOS transistor and the source of the second-conduction-type second MOS transistor; and
an inverter connected between the drain of the second-conduction-type first MOS transistor and the drain of the first-conduction-type second MOS transistor and facing the resistance and that outputs a delay signal that is later than an input signal by a delay time proportional to threshold voltages of the first-conduction-type first MOS transistor and the second-conduction-type second MOS transistor that vary as a function of temperature.

9. The delay cell structure of claim 8, wherein the inverter comprises:
a second-conduction-type third MOS transistor having a source connected to the drain of the second-conduction-type first MOS transistor and a gate connected to the signal input terminal; and
a first-conduction-type third MOS transistor having a drain connected to the drain of the second-conduction-type third MOS transistor, a gate connected to the signal input terminal, and a source connected to the drain of the first-conduction-type second MOS transistor.

10. The delay cell structure of claim 8, further comprising:
a first dummy resistor connected between the power supply terminal and the first-conduction-type first MOS transistor; and
a second dummy resistor connected between the ground terminal and the second-conduction-type second MOS transistor,
wherein the resistance is a short circuit between the source of the first-conduction-type first MOS transistor and the source of the second-conduction-type second MOS transistor.

11. A delay cell comprising:
an inverter having an input terminal and an output terminal; and
a first current mirror and a second current mirror, each current mirror disposed between a common power supply terminal and a common ground terminal and having current mirror transistors that operate more slowly at a first temperature than they operate at a second temperature higher than the first temperature, the first current mirror and the second current mirror configured to provide a power supply delay to the inverter.

12. The delay cell of claim 11, further comprising a resistance disposed in parallel with the inverter and coupled between the first current mirror and the second current mirror.

13. The delay cell of claim 11, wherein each current mirror transistor operates in a dip saturation region.

14. The delay cell of claim 11, wherein when temperature decreases, threshold voltages of the current mirror transistors increase and when temperature increases, threshold voltages of the current mirror transistors decrease.

15. The delay cell of claim 12, wherein a predetermined delay time between a signal input to the inverter and a signal output from the inverter is determined by a resistance value of the resistance.

16. The delay cell of claim 15, wherein the resistance value of the resistance varies less with temperature than a threshold voltage of the current mirror transistors varies with temperature.

17. The delay cell of claim 11, further comprising:
a first resistance between the first current mirror and the power supply terminal; and
a second resistance coupled between the second current mirror and the ground terminal.

18. The delay cell of claim 17, wherein the first resistance and the second resistance have substantially the same resistance value.
